(19) United States
(12) Patent Application Publication
(10) Pub. No.: US 2021/0010152 A1
(43) Pub. Date: Jan. 14, 2021

(54) SEMICONDUCTOR CRYSTAL GROWTH APPARATUS

(71) Applicant: Zing Semiconductor Corporation, Shanghai (CN)

(72) Inventors: Weimin Shen, Shanghai (CN); Gang Wang, Shanghai (CN); Xianliang Deng, Shanghai (CN); Hanyi Huang, Shanghai (CN); Wee Teck Tan, Shanghai (CN)

(21) Appl. No.: 16/904,570

(22) Filed: Jun. 18, 2020

(30) Foreign Application Priority Data
Jun. 18, 2019 (CN) 201910527728.2

(51) Int. Cl. C30B 15/14; C30B 15/00

(52) U.S. Cl. CPC C30B 15/14; C30B 15/002

(57) ABSTRACT

The invention provides a semiconductor crystal growth device. It comprises: a furnace body; a crucible arranged inside the furnace body for containing a silicon melt; a heater having a graphite cylinder arranged around the crucible for heating the silicon melt; a pulling device arranged on the top of the furnace body for pulling out the silicon crystal ingot from the silicon melt; and a magnetic field applying device for applying a horizontal magnetic field to the silicon melt in the crucible; wherein a plurality of grooves are provided on the side wall of the graphite cylinder along the axis direction of the graphite cylinder, and a depth of the grooves in the direction of the magnetic field is smaller than a depth of the grooves perpendicular to the direction of the magnetic field. According to the semiconductor crystal growth device of the present invention, the temperature distribution inside the melt silicon and quality of the semiconductor crystal and the quality of semiconductor crystal growth are improved.

### CROSS-REFERENCE TO RELATED APPLICATIONS

This application claims priority to P.R.C. Patent Application No. 201910527728.2 titled “a semiconductor crystal growth apparatus” filed on Jun. 18, 2019, with the State Intellectual Property Office of the People's Republic of China (SIPO).

### TECHNICAL FIELD

The present invention relates to the field of semiconductor technology, and in particular, to a semiconductor crystal growth device.

### BACKGROUND

The Czochralski Process (CZ) method is an important method for preparing single crystal silicon for semiconductor and solar energy. The high-purity silicon material placed in the crucible is heated by a thermal field composed of a carbon material to melt it, and then the seed is melted by The crystal is immersed in the melt and undergoes a series of (introduction, shoulder, equal diameter, finishing, cooling) processes to obtain a single crystal rod.

In the growth of semiconductor single crystal silicon or solar single crystal silicon using the CZ method, the temperature distribution of the crystal and the melt directly affects the quality and growth rate of the crystal. During the growth of CZ crystals, due to the existence of thermal convection in the melt, the distribution of trace impurities is uneven and growth stripes are formed. Therefore, how to suppress the thermal convection and temperature fluctuation of the melt during the crystal pulling process has been a widespread concern.

The crystal growth technology under a magnetic field generator (called MCZ) applies a magnetic field to a silicon melt as a conductor, subjecting the melt to a Lorentz force opposite to its direction of movement, obstructing convection in the melt and increasing the viscosity of the melt reduces impurities such as oxygen, boron, and aluminum from the quartz crucible into the melt, and then into the crystal, so that the grown silicon crystal can have a controlled oxygen content from low to high range, reducing The impurity stripes are widely used in semiconductor crystal growth processes. A typical MCZ technology is so called horizontal magnetic field crystal growth (HMCZ) technology, which applies a horizontal magnetic field to a semiconductor melt, and is widely used for the growth of large-sized and demanding semiconductor crystals.

In the crystal growth technology under a horizontal magnetic field device (HMCZ), the crystal growth furnace, thermal field, crucible, and silicon crystals are as symmetrical as possible in the circumferential direction, and the crucible and crystal rotation make the temperature distribution in the circumferential direction tends to be uniform. However, the magnetic field lines of the magnetic field applied during the application of the magnetic field pass from one end of the silicon melt in the quartz crucible to the other end in parallel. The Lorentz force generated by the rotating silicon melt is different in all directions in the circumferential direction, so the silicon melt flow and temperature distribution are inconsistent in the circumferential direction.

As shown in FIG. 1A and FIG. 1B, schematic diagrams of a temperature distribution below an interface between a crystal grown crystal and a melt in a semiconductor crystal growth apparatus are shown. Among them, FIG. 1A shows a graph of measured test points distributed on the horizontal surface of the silicon melt in the crucible, where one point is tested at an angle of θ=45° at a distance of 25 mm below the melt liquid level and a distance of L=250 mm from the center. FIG. 1B is a curve of the temperature distribution obtained by simulation calculation and test along each point at an angle θ with the X axis in FIG. 1A, where the solid line represents the temperature distribution map obtained by simulation calculation, and the dot diagram indicates the measured test method adopted distribution of temperature obtained. In FIG. 1A, the arrow A shows that the direction of rotation of the crucible is counterclockwise, and the arrow B shows that the direction of the magnetic field crosses the diameter of the crucible along the Y-axis direction. It can be seen from FIG. 1B that during the growth of the semiconductor crystal, both the results of the simulation calculation and the measured test method have shown that the temperature fluctuated on the circumference below the interface of a semiconductor crystal and the silicon melt liquid level changes with the angle during the growth of the semiconductor crystal.

According to the Voronkov crystal growth theory, the thermal equilibrium equation of the interface of the crystal and the liquid surface is as follows,

PS*LQ=Kc*Gc−Km*Gm.

Among them, LQ is the potential of silicon melt to silicon crystal phase transition, Kc, Km represent the thermal conductivity of the crystal and the melt, respectively; Kc, Km, and LQ are the physical properties of the silicon material; PS represents the crystal crystallization speed along the on-pull elongation direction that is approximately the pulling speed of the crystal; Gc, Gm are the temperature gradient (dT/dZ) of the crystal and the melt at the interface, respectively. Because the temperature below the interface of the semiconductor crystal and the melt exhibits periodic fluctuations with the change of the circumferential angle during the growth of semiconductor crystals, that is, the Gc of the temperature gradient (dT/dZ) of the crystal and the melt as the interface, Gm fluctuates. Therefore, the crystallization speed PS of the crystal in the circumferential angle direction fluctuates periodically, which is not conducive to controlling the quality of crystal growth.

For the reasons above, it is necessary to propose a new semiconductor crystal growth device to solve the problems in the prior art.

### SUMMARY

A series of simplified forms of concepts are introduced in the Summary of the Invention section, which will be described in further detail in the Detailed Description section. The summary of the invention is not intended to limit the key features and essential technical features of the claimed invention, and is not intended to limit the scope of protection of the claimed embodiments.

An objective of the present invention is to provide a semiconductor crystal growth apparatus, the semiconductor crystal growth apparatus comprises:
a furnace body;
a crucible arranged inside the furnace body for containing a silicon melt;
a heater having a graphite cylinder arranged around the crucible for heating the silicon melt;
a pulling device arranged on the top of the furnace body for pulling out the silicon crystal ingot from the silicon melt; and
a magnetic field applying device for applying a horizontal magnetic field to the silicon melt in the crucible;
wherein a plurality of grooves are provided on the side wall of the graphite cylinder along the axis direction of the graphite cylinder, and a depth of the grooves in the direction of the magnetic field is smaller than a depth of the grooves perpendicular to the direction of the magnetic field.

In accordance with some embodiments, the grooves comprise a plurality of first grooves opened from top to bottom and a plurality of second grooves opened from bottom to top on the side wall of the graphite cylinder, and the first grooves and the second grooves are alternatively arranged.

In accordance with some embodiments, a depth of the first grooves in the direction of the magnetic field is smaller than a depth of the first grooves perpendicular to the direction of the magnetic field; and/or

a depth of the second grooves in the direction of the magnetic field is smaller than a depth of the second grooves perpendicular to the direction of the magnetic field.

In accordance with some embodiments, the depth of the plurality of grooves change gradually along the circumferential direction of the graphite cylinder, and the depth of the plurality of grooves is the smallest in the direction of the magnetic field, and the depth of the plurality of grooves is the largest in the direction perpendicular to the magnetic field.

In accordance with some embodiments, the depth of the plurality of grooves in the direction of the magnetic field is about 60%-95% of the depth of the plurality of grooves in the direction perpendicular to the magnetic field.

According to the semiconductor crystal growth device of the present invention, by tuning the depth of the grooves opened on the side wall of the graphite cylinder of the heater, the calorific value of the current in the circumferential direction is tuned. According to this, by tuning the depth of the groove opened on the sidewall of the graphite cylinder, the heat provided by the heater to heat the silicon melt is tuned to compensate for the asymmetry of the silicon melt flow due to the applied horizontal magnetic field, and to reduce the influence of the melt temperature fluctuation; furthermore, it can regulate the temperature distribution of the silicon melt below the interface between the silicon ingot and the silicon melt, so that the fluctuation of the temperature distribution of the silicon melt due to the applied horizontal magnetic field can be tuned and effectively improved. The uniformity of the temperature distribution of the liquid surface of the silicon melt is improved, thereby improving the uniformity of the crystal growth rate and the quality of the crystal pulling.

### BRIEF DESCRIPTION OF THE DRAWINGS

Exemplary embodiments will be more readily understood from the following detailed description when read in conjunction with the appended drawings, in which:

FIGS. 1A and 1B are schematic diagrams of the temperature distribution below the interface between a crystal and a melt in a semiconductor crystal growth device;

FIG. 2 is a schematic structural diagram of a semiconductor crystal growth device according to the present invention;

FIG. 3 is a schematic diagram of a heater structure according to a semiconductor crystal growth device;

FIG. 4 is a schematic cross-sectional arrangement of a heater and a crucible according to a semiconductor crystal growth device;

FIG. 5 is a schematic diagram of the depth of the grooves of the heater sidewall in a semiconductor crystal growth device;

FIG. 6 is a schematic diagram of a depth of a grooves of a heater sidewall in a semiconductor crystal growth apparatus according to an embodiment of the present invention.

### DETAILED DESCRIPTION

The embodiments of the present invention are described below by way of specific examples, and those skilled in the art can readily understand other advantages and effects of the present invention from the disclosure of the present disclosure. The present invention may be embodied or applied in various other specific embodiments, and various modifications and changes can be made without departing from the spirit and scope of the invention.

In the following description, while the invention will be described in conjunction with various embodiments, it will be understood that these various embodiments are not intended to limit the invention. On the contrary, the invention is intended to cover alternatives, modifications and equivalents, which may be comprised within the scope of the invention as construed according to the Claims. Furthermore, in the following detailed description of various embodiments in accordance with the invention, numerous specific details are set forth in order to provide a thorough understanding of the invention. However, it will be evident to one of ordinary skill in the art that the invention may be practiced without these specific details or with equivalents thereof. In other instances, well known methods, procedures, components, and circuits have not been described in detail as not to unnecessarily obscure aspects of the invention.

To understand the invention thoroughly, the following descriptions will provide detail steps to explain a method for crystal growth control of a shouldering process according to the invention. It is apparent that the practice of the invention is not limited to the specific details familiar to those skilled in the semiconductor arts. The preferred embodiment is described as follows. However, the invention has further embodiments beyond the detailed description.

The terminology used herein is for the purpose of describing particular embodiments only and is not intended to be limiting of example embodiments. As used herein, the singular forms “a,” “an” and “the” are intended to comprise the plural forms as well, unless the context clearly indicates otherwise. It will be further understood that the terms “comprises,” “comprising,” “includes” and/or “including,” if used herein, specify the presence of stated features, integers, steps, operations, elements and/or components, but do not preclude the presence or addition of one or more other features, integers, steps, operations, elements, components and/or groups thereof

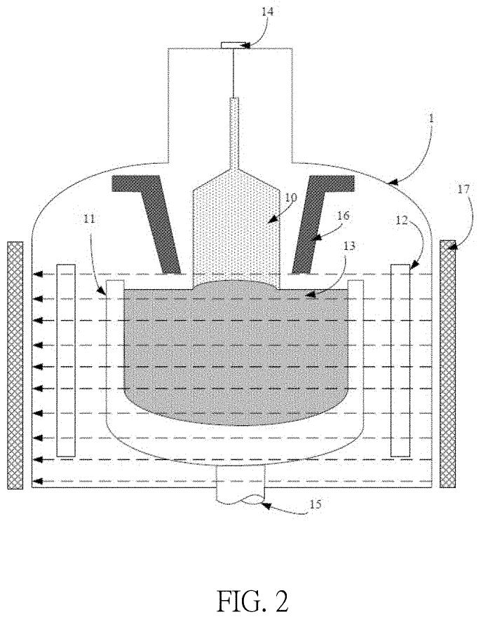

Referring to FIG. 2, a schematic structural diagram of a semiconductor crystal growth device according to one embodiment of the present invention is shown. The semiconductor crystal growth device includes a furnace body 1, a crucible 11 is disposed in the furnace body 1, and a heater 12 is provided on the outer side of the crucible 11 for heating. The crucible 11 contains a silicon melt 13. The crucible 11 is composed of a graphite crucible and a quartz crucible sheathed in the graphite crucible. The graphite crucible receives the heat provided by the heater to melt the polycrystalline silicon material in the quartz crucible to form a silicon melt. . Each quartz crucible is used for a batch semiconductor growth process, and each graphite crucible is used for a multi-batch semiconductor growth process.

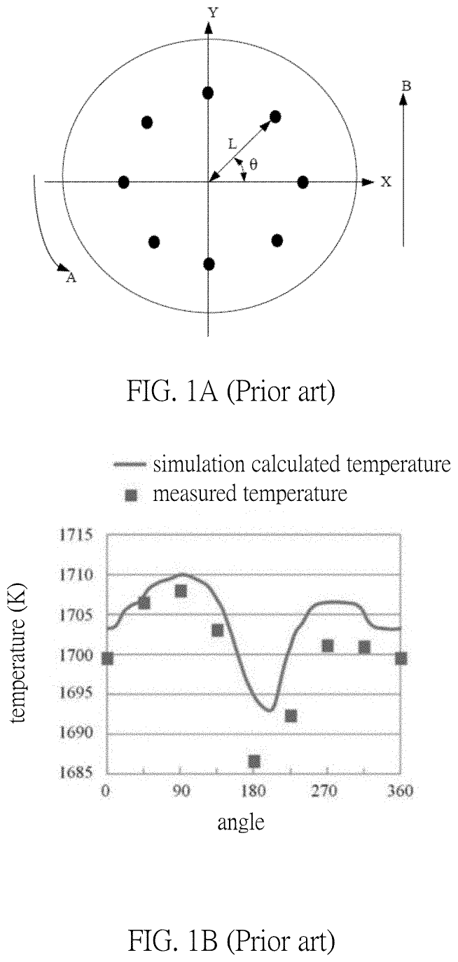

A pulling device 14 is provided on the top of the furnace body 1. Driven by the pulling device 14, a seed crystal may be pulled and pulled out of a silicon ingot 10 from the liquid level of the silicon melt, and a heat shield device is provided around the silicon ingot 10. The heat shield device, for example, as shown in FIG. 1, comprises a deflector 16, which is provided in a barrel type, serves as a heat shield device to isolate the quartz crucible during the crystal growth process and the thermal radiation generated by the silicon melt in the crucible on the surface of the crystal increases the cooling rate and axial temperature gradient of the ingot, and increases the number of crystal growth. On the other hand, it affects the thermal field distribution on the surface of the silicon melt and avoids the axial temperature gradient between the center and the edge is too large to ensure stable growth between the crystal ingot and the liquid level of the silicon melt. At the same time, the baffle is also used to guide the inert gas introduced from the upper part of the crystal growth furnace to make it a large flow rate passes through the surface of the silicon melt to achieve the effect of controlling the oxygen content and impurity content in the crystal. During the growth of the semiconductor crystal, driven by the pulling device 14, the silicon ingot 10 passes vertically through the deflector 16.

In order to achieve stable growth of the silicon ingot, a driving device 15 for driving the crucible 11 to rotate and move up and down is provided at the bottom of the furnace body 1. The driving device 15 may drive the crucible 11 to keep rotating during the crystal pulling process to reduce the asymmetry of the heat of the silicon melt for equal-diameter growth of the silicon ingot.

In order to hinder the convection of the silicon melt, increase the viscosity in the silicon melt, reduce impurities such as oxygen, boron, and aluminum from the quartz crucible into the melt and then into the crystal, so that the grown silicon crystal can have the controlled low-to-high range oxygen content reduces impurity streaks. The semiconductor growth device further comprises a magnetic field applying device 17 located outside the furnace body 1 to apply a horizontal magnetic field to the silicon melt in the crucible.

Since the horizontal magnetic field lines of the magnetic field applied by the magnetic field applying device 17 pass from one end of the silicon melt in the crucible to the other end in parallel (see the dotted arrow in FIG. 2), the Lorentz force generated by the rotating silicon melt is on the circumference. The directions are different, so the flow and temperature distribution of the silicon melt are inconsistent in the circumferential direction, where the temperature along the direction of the magnetic field is higher than that in the direction perpendicular to the magnetic field. The inconsistency of the flow and temperature of the silicon melt manifests as the temperature of the melt below the interface of the semiconductor crystal and the melt fluctuates with the change of the angle, so that the crystallization speed PS of the crystal fluctuates, so that the semiconductor growth speed appears inconsistent on the circumference. Such non-uniformity is not suited for the quality control of semiconductor crystal growth.

In a conventional semiconductor crystal growth apparatus, a cylinder provided with grooves of equal depth in the side wall of the heater is used to form a current loop. Specifically, opposite current input electrodes and current output electrodes are provided on the circumference of the graphite cylinder, and the current flowing from the current input electrodes flows to the current output electrodes in two directions on the circumference of the heater, thereby forming a parallel connection current loop. Because graphite has a certain resistance, heat is generated during the current flowing through the graphite cylinder to provide a heat source for heating the silicon melt. In this heating method, the heater generates heat uniformly along the circumferential direction of the graphite cylinder. Therefore, the crucible containing the silicon melt receives the same amount of heat in the circumferential direction.

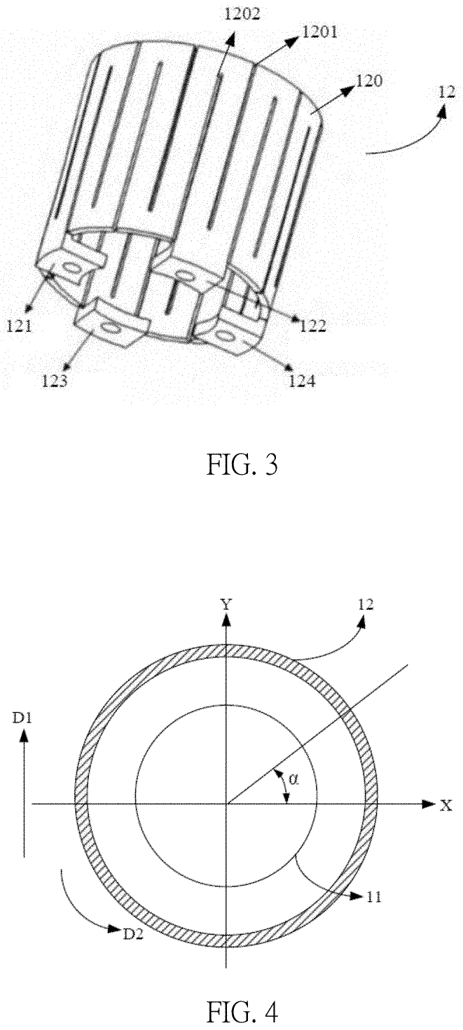

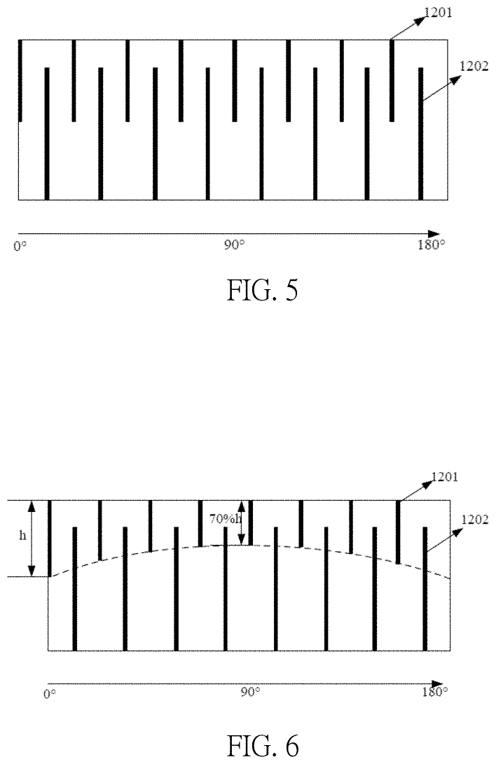

Referring to FIG. 3, a schematic structural diagram of a heater in a semiconductor crystal growth apparatus is shown. The heater 12 comprises a graphite cylinder 120, and current input electrodes 121, 122, and current output electrodes 123, 124 disposed below the graphite cylinder; a plurality of grooves 1201 and a plurality of grooves 1202 are provided along the axis direction of the heater, wherein the grooves 1201 are opened along the side wall of the graphite cylinder 120 of the heater from top to bottom, while the grooves 1202 are opened along the sidewall of the graphite cylinder 120 of the heater from bottom to top, and the grooves 1201 and the grooves 1202 are alternatively arranged along the circumferential direction of the graphite cylinder. In the prior art, the grooves 1201 just opened along the side wall of the graphite cylinder of the heater have the same depth. Referring to FIG. 4, a schematic diagram of a cross-sectional arrangement of a heater and a crucible according to a semiconductor crystal growth apparatus is shown, where arrow D1 shows the direction of the horizontal magnetic field, arrow D2 shows the direction of rotation of the crucible 11, and the side wall of the graphite cylinder is provided with grooves. FIG. 5 shows a schematic diagram of the depth of the groove of the heater side wall in a semiconductor crystal growth device according to one embodiment of the present invention; wherein a plurality of grooves 1201 with equal depth and from the bottom are opened along the side wall of the graphite cylinder of the heater from top to bottom, while a plurality of grooves 1202 with equal depth are opened up. Since the grooves formed on the graphite cylinder have the same depth, the heat generated during the current flowing through the graphite cylinder is equal along the circumferential direction of the graphite cylinder, so that the silicon melt in the crucible is equally heated along the circumferential direction.

In order to overcome the inconsistency of the flow and temperature distribution of the silicon melt due to the magnetic field in the circumferential direction when a magnetic field in the horizontal direction is applied, a pair of grooves with different depths for the graphite cylinder in the heater is used in the present invention, specifically, the depth of the grooves along the direction of the magnetic field are smaller than the depth of the grooves perpendicular to the direction of the magnetic field.

By tuning the depth of the grooves opened on the side wall of the graphite cylinder of the heater, thereby tuning the calorific value of the current in the circumferential direction. Specifically, the depth of the grooves opened in the direction perpendicular to the magnetic field are deeper to generate more heat, and the depth of the grooves opened in the direction of the magnetic field are shallower to generate less heat. According to this, by tuning the depth of the grooves opened on the side wall of the graphite cylinder, the heat provided by the heater to heat the silicon melt is tuned to compensate for the asymmetry of the melt flow due to the applied horizontal magnetic field caused temperature fluctuation; furthermore, it can tune the temperature distribution of the silicon melt below the interface between the silicon ingot and the silicon melt, so that the fluctuation of the temperature distribution of the silicon melt due to the applied horizontal magnetic field can be tuned, and the silicon is effectively improved. The uniformity of the temperature distribution of the melt liquid surface improves the uniformity of the crystal growth rate and improves the crystal pulling quality.

At the same time, since the internal temperature distribution of the silicon melt is more uniform, this further improves the uniformity of the crystal growth rate, makes the oxygen content distribution in the grown semiconductor crystal uniform, and improves the uniformity of the oxygen content distribution in the crystal, therefore, reduces the defects in crystal growth.

According to an embodiment of the present invention, the depth of the grooves vary progressively along the circumferential direction of the graphite cylinder, wherein the depth of the grooves are the smallest in the direction of the magnetic field and are the largest in the direction perpendicular to the magnetic field. The graphite cylinder of the heater of the semiconductor growth device of the present invention will be exemplarily described with reference to FIGS. 3, 4 and 6.

As shown in FIG. 3, the heater comprises a graphite cylinder 120, and current input electrodes 121 and 122 and current output electrodes 123 and 124 disposed under the graphite cylinder; on the side wall of the graphite cylinder 120 of the heater 12, a plurality of grooves 1201 and a plurality of grooves 1202 are provided along the axis of the heater, wherein the grooves 1201 are opened from top to bottom along the side wall of the graphite cylinder 120 of the heater, and the grooves 1202 are from bottom to top along the graphite cylinder 120 of the heater, while the grooves 1201 and 1202 are alternatively arranged along the circumferential direction of the graphite cylinder.

Referring to FIG. 4, a schematic diagram of a cross-sectional arrangement of a heater and a crucible according to a semiconductor crystal growth apparatus is shown, where arrow D1 shows the direction of the horizontal magnetic field, and arrow D2 shows the direction of rotation of the crucible 11, and heating grooves are formed in the side wall of the graphite cylinder of the device 12. Wherein, grooves of different depths are provided at different positions on the side wall of the graphite cylinder, that is, as the angle α in FIG. 4 changes, grooves of different depths are provided at different positions of the graphite cylinder.

FIG. 6 shows a schematic diagram of the depth of the heater sidewall groove in a semiconductor crystal growth apparatus according to an embodiment of the present invention; wherein, as the angle α in FIG. 4 changes from 0° to 90° (ie from the direction perpendicular to the magnetic field to the direction along the magnetic field, the depth of the grooves 1201 gradually decreased (as shown by the dotted line in FIG. 6); a changes from 90° to 180° (that is, from the direction along the magnetic field to perpendicular to the direction of the magnetic field), the depth of the grooves 1201 gradually increased (as shown by the dotted line in FIG. 6). In this case, as the angle α in FIG. 4 changes from 0° to 90° (that is, from the direction perpendicular to the magnetic field to the direction along the magnetic field), the heat provided by the heater to heat the silicon melt in the crucible gradually decreased, α changes from 90° to 180° (that is, from the direction along the magnetic field to the direction perpendicular to the magnetic field), the heat provided by the heater to heat the silicon melt in the crucible gradually increased. This trend is exactly opposite to the trend of the influence of the applied horizontal magnetic field on the temperature of the silicon melt in FIG. 1B, so as to make up for the influence of the applied horizontal magnetic field on the temperature of the silicon melt, and further improve the case of applying the horizontal magnetic field, as well as the uniformity distribution of the temperature of the silicon melt.

It should be understood that the curve of the depth of the groove 1201 shown in FIG. 6 is a gradual change is only exemplary, it may also be a linear gradual change or other forms of gradual change.

According to an example of the present invention, the depth of the groove in the direction of the magnetic field is about 60%-95% of the depth of the groove in the direction perpendicular to the magnetic field. As shown in FIG. 6, as the angle α in FIG. 4 changes from 0° to 90° (that is, from the direction perpendicular to the magnetic field to the direction along the magnetic field), the depth h of the grooves 1201 gradually decreased to 70% h.

It should be understood that FIG. 6 shows that the grooves with varying depths are formed on the side walls of the heater graphite cylinder from top to bottom are only exemplary, and can also be provided on the heater graphite cylinder. Grooves with varying depths are formed on the side wall from bottom to top, and grooves with varying depths are formed on the side wall of the graphite cylinder of the heater from top to bottom and from bottom to top, so that in the direction of the magnetic field, the depth of the grooves is less than the depth of the grooves perpendicular to the direction of the magnetic field, and the above arrangement forms can all achieve the technical effect of the present invention. s

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantage.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

What is claimed is:

1. A semiconductor crystal growth apparatus, comprising:
a furnace body;
a crucible arranged inside the furnace body for containing a silicon melt;
a heater having a graphite cylinder arranged around the crucible for heating the silicon melt;
a pulling device arranged on the top of the furnace body for pulling out the silicon crystal ingot from the silicon melt; and
a magnetic field applying device for applying a horizontal magnetic field to the silicon melt in the crucible;
wherein a plurality of grooves are provided on the side wall of the graphite cylinder along the axis direction of the graphite cylinder, and a depth of the grooves in the direction of the magnetic field is smaller than a depth of the grooves perpendicular to the direction of the magnetic field.

2. The apparatus according to claim 1, wherein the plurality of groove comprises a plurality of first grooves opened from top to bottom and a plurality of second grooves opened from bottom to top on the side wall of the graphite cylinder, and the first grooves and the second grooves are alternatively arranged.

3. The apparatus according to claim 2, wherein
a depth of the first grooves in the direction of the magnetic field is smaller than a depth of the first groove perpendicular to the direction of the magnetic field; and/or
a depth of the second grooves in the direction of the magnetic field is smaller than a depth of the second groove perpendicular to the direction of the magnetic field.

4. The apparatus according to claim 1, wherein the depth of the plurality of grooves change gradually along the circumferential direction of the graphite cylinder, and the depth of the plurality of grooves is the smallest in the direction of the magnetic field, and the depth of the plurality of grooves is the largest in the direction perpendicular to the magnetic field.

5. The apparatus according to claim 4, wherein the depth of the plurality of grooves in the direction of the magnetic field is about 60%-95% of the depth of the plurality of grooves in the direction perpendicular to the magnetic field.
